(19) United States
(12) Patent Application Publication
(10) Pub. No.: US 2010/0012944 A1
(43) Pub. Date: Jan. 21, 2010

(54) THIN FILM TRANSISTOR SUBSTRATE AND THIN FILM TRANSISTOR OF DISPLAY PANEL AND METHOD OF MAKING THE SAME

(76) Inventors: An-Thung Cho, Hsin-Chu (TW); Chin-Wei Hu, Hsin-Chu (TW); Ming-Wei Sun, Hsin-Chu (TW); Chih-Wei Chao, Hsin-Chu (TW); Chia-Tien Peng, Hsin-Chu (TW); Kun-Chih Lin, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 12/400,768

(22) Filed: Mar. 9, 2009

(30) Foreign Application Priority Data
Jul. 17, 2008 (TW) 097127149

(51) Int. Cl. H01L 29/04; H01L 21/84

(52) U.S. Cl. 257/72; 438/151; 257/E21.411; 257/E29.002

(57) ABSTRACT

A thin film transistor (TFT) formed on a transparent substrate is provided. The thin film transistor includes a patterned semiconductor layer, a gate insulating layer disposed on the patterned semiconductor layer, a gate electrode disposed on the gate insulating layer, and a patterned light-absorbing layer. The patterned semiconductor layer includes a channel region, and a source region and a drain region disposed on two opposite sides of the channel region in the pattern semiconductor layer. The patterned light-absorbing layer is disposed between the transparent substrate and the patterned semiconductor layer.

### BACKGROUND OF THE INVENTION

1. Field of the Invention

The present invention relates to a thin film transistor substrate, a thin film transistor of a display panel and a fabrication method thereof, and more particularly, to a thin film transistor, which can prevent photo leakage current, and a fabrication method thereof.

2. Description of the Prior Art

FIG. 1 is a schematic diagram showing a thin film transistor of a conventional liquid crystal display panel. As illustrated in FIG. 1, a conventional thin film transistor 10 is formed on a thin film transistor substrate 1 of the liquid crystal display panel. The thin film transistor 10 includes a semiconductor layer, a gate insulating layer 18 disposed on the semiconductor layer, and a gate electrode 20 disposed on the gate insulating layer 18. The semiconductor layer includes a channel region 12, a source region 14 and a drain region 16 disposed on two opposite sides of the channel region 12.

Being a non self-emitting device, the liquid crystal display panel consequently requires a backlight module to provide backlight as light source. The thin film transistor is a switch device of a pixel in a liquid crystal display, wherein a gate electrode, connected with a scan line, can be turned on by the scan line, a source region is connected with a data line for receiving signals, and a drain region is connected with a pixel electrode. By way of the above-mentioned connection, the thin film transistor will be turned on when the gate electrode receives a gate voltage. While the thin film transistor is turned on, the signals from the data line will be delivered to the pixel electrode through the source region, the channel region and the drain electrode in sequence. And at the same time, a liquid capacitor is formed between the pixel electrode and a common electrode, such that the transmittance can be changed to control the gray-scale brightness. However, as illustrated in FIG. 1, the channel region 12 of the conventional thin film transistor 10 is wholly under the illumination exposure of the backlight source or the external light source, which accordingly results in the increase of the photo leakage current, and influences normal operation of the thin film transistor 10.

### SUMMARY OF THE INVENTION

One goal of the present invention is to provide a thin film transistor of a display panel and a fabrication method thereof to reduce the photo leakage current of the thin film transistor.

To achieve the above-mentioned goal, the present invention provides a kind of thin film transistor formed on a transparent substrate. The thin film transistor includes a patterned semiconductor layer, a gate insulating layer disposed on the patterned semiconductor layer, and a gate electrode disposed on the gate insulating layer, and a patterned light-absorbing layer. The patterned semiconductor layer includes a channel region, and a source region and a drain region respectively disposed on two opposite sides of the channel region in the patterned semiconductor layer. The patterned light-absorbing layer is disposed between the transparent substrate and the patterned semiconductor layer.

To achieve the aforementioned goal, the present invention further provides a thin film transistor substrate, which is suitable for a display panel, includes a transparent substrate and a plurality of thin film transistors disposed on the transparent substrate. Each thin film transistor includes a patterned semiconductor layer, a gate insulating layer disposed on the patterned semiconductor layer, and a gate electrode disposed on the gate insulating layer, and a patterned light-absorbing layer. The patterned semiconductor layer includes a channel region, a source region and a drain region respectively disposed on two opposite sides of the channel region in the patterned semiconductor layer. The patterned light-absorbing layer is disposed between the transparent substrate and the patterned semiconductor layer.

To achieve the aforementioned goal, the invention further provides a fabrication method of a thin film transistor, which includes following steps. A transparent substrate is provided. Then, a patterned light-absorbing layer and a patterned semiconductor layer are sequentially formed on the transparent substrate, wherein the patterned light-absorbing layer substantially shields the patterned semiconductor layer. Subsequently, a thin film transistor is formed on the patterned semiconductor layer.

The thin film transistor of the display panel of the present invention utilizes the light-absorbing layer to shield the backlight illuminated from the backlight module and to decrease the direct-emitting backlight on the patterned semiconductor layer. Consequently, the problem of photo leakage current of the thin film transistor can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing a thin film transistor of a conventional liquid crystal display panel.

FIG. 2 to FIG. 5 are schematic diagrams of a fabrication method of a thin film transistor of display panel according to a preferred embodiment of the present invention.

FIG. 6 and FIG. 7 are schematic diagrams illustrating two thin film transistors of another two embodiments of the present invention.

FIG. 8 illustrates a drain current (ID) versus gate-source voltage (VGS) plot of the thin film transistor.

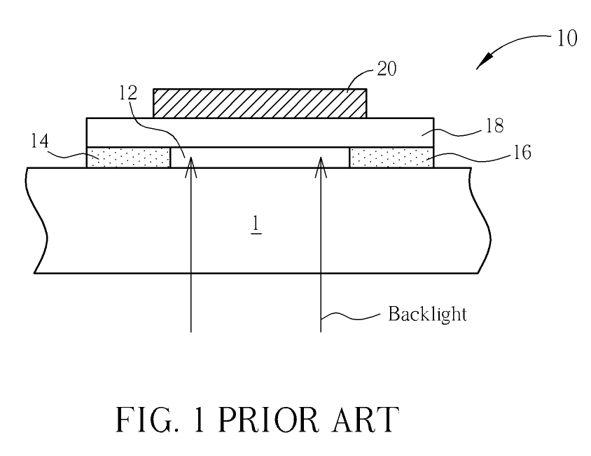

### DETAILED DESCRIPTION

To provide a better understanding of the presented invention, preferred embodiments will be detailed as follows. The preferred embodiments of the present invention are illustrated in the accompanying drawings with numbered elements to elaborate the contents and effects to be achieved.

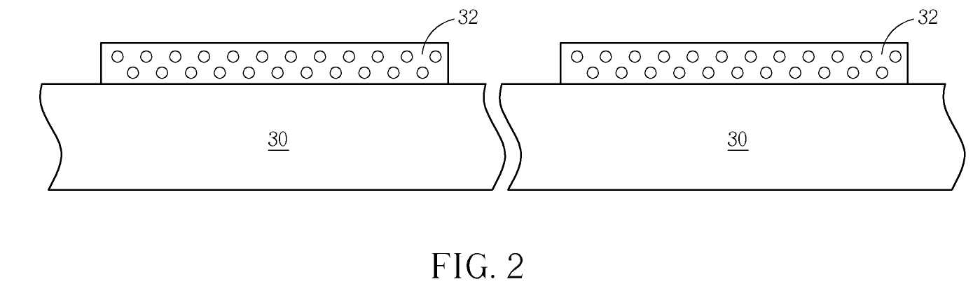

FIG. 2 to FIG. 5 are schematic diagrams illustrating a fabrication method of a thin film transistor of a display panel according to a preferred embodiment of the present invention. In this embodiment, the display panel is a liquid crystal display panel but not limited. As illustrated in FIG. 2, a transparent substrate 30 is firstly provided. The transparent substrate 30 is served as the thin film transistor substrate of the liquid crystal display panel, and may be a substrate made of transparent material e.g. a glass substrate, a quartz substrate or a plastic substrate. And then a pattered light-absorbing layer 32 is formed on the transparent substrate 30. The pattered light-absorbing layer 32 may include a silicon-rich dielectric layer such as a silicon-rich silicon oxide layer (SiOx), a silicon-rich silicon nitride layer (SiNy), a silicon-rich silicon oxynitride layer (SiOxNy), a silicon-rich silicon carbide layer (SiCz), a silicon-rich silicon oxycarbide layer (SiOxCz), a hydrogenated silicon-rich silicon oxide layer (SiHwOx), a hydrogenated silicon-rich silicon nitride layer (SiHwNy), a hydrogenated silicon-rich silicon oxynitride layer (SiHwOxNy), or at least one of the aforementioned materials, or stacked layers thereof or other silicon-rich compounds, wherein 0<w<1, 0<x<2, 0<y<1.67, 0<z<1. When the material of the silicon-rich dielectric is silicon-rich silicon oxide, the molecular formula of the silicon-rich silicon oxide is SiOₓ, wherein x is larger than 0 but smaller than 2. When the material of the silicon-rich dielectric is silicon-rich silicon nitride, the molecular formula of the silicon-rich silicon nitride is SiNy, wherein y is larger than 0 but smaller than 4/3 (about 1.67). When the material of the silicon-rich dielectric is silicon-rich silicon oxynitride layer, the molecular formula of the silicon-rich silicon oxynitride is SiOₓNy, wherein (X+Y) is larger than 0 but smaller than 2.

In the present embodiment, the silicon-rich dielectric is deposited and formed by such as plasma enhanced chemical vapor deposition (PECVD) using mixing gases of e.g. silane (SiH₄), nitrous oxide (N₂O) or ammonia (NH₃) in a well-suited composition proportion. Accordingly, a silicon-rich silicon oxide layer, a. silicon-rich silicon nitride layer and a silicon-rich silicon oxynitride layer can be deposited and formed. For instance, a silicon-rich silicon oxide layer can be deposited by pouring a mixing gas of SiH₄ and N₂O, a silicon-rich silicon nitride layer can be deposited by pouring a mixing gas of SiH₄ and NH₃, and a silicon-rich silicon oxynitride layer can be deposited by pouring a mixing gas of SiH₄, N₂O and NH₃. Furthermore, the index of refraction becomes higher while the amount of silicon in silicon-rich dielectric becomes higher, wherein the index of refraction is between 1.7 and 3.7 and the thickness of dielectric is approximately between 100 nm and 300 nm.

The pattered light-absorbing layer 32 is preferably a nanocrystalline silicon dielectric layer, wherein the diameter of the nanocrystalline silicon of the nanocrystalline silicon dielectric layer is substantially between 5 angstrom (Å) and 500 angstrom (Å), and the nanocrystalline silicon dielectric layer may be formed by a low-temperature laser annealing process but not limited. The pattered light-absorbing layer 32 is used to absorb the backlight coming from the bottom of the transparent substrate 30, such that the photo leakage current of the thin film transistor due to backlight illumination is prevented.

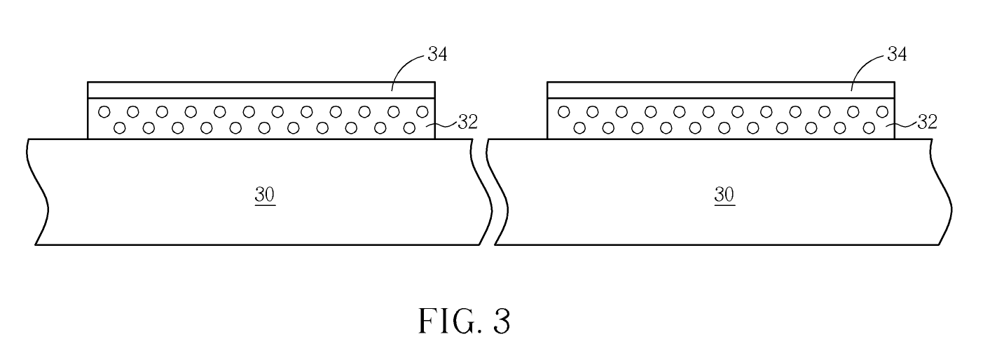

As illustrated in FIG. 3, a buffer layer 34 can be selectively formed either on the transparent substrate 30 or on the pattered light-absorbing layer 32. The buffer layer 34 prevents the impurities of the transparent substrate 30, which would influence the normal operation of the thin film transistor, from diffusing into the semiconductor layer in subsequent process. In the present embodiment, the buffer layer 34 is not restricted to be formed on the pattered light-absorbing layer 32, and may also be formed on the transparent substrate 30 prior to the formation of the pattered light-absorbing layer 32. In addition, the buffer layer 34 may be a single-layered structure such as a buffer oxide layer or a buffer oxynitride layer, or may be a composite-layered structure, which includes both a buffer oxide layer and a buffer oxynitride layer.

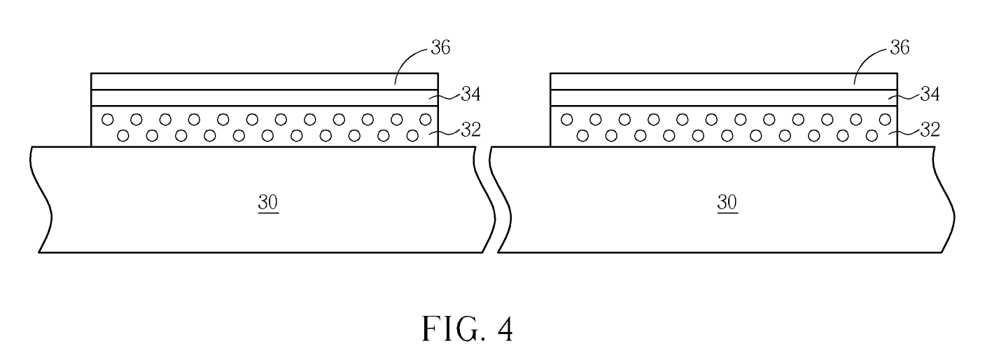

As illustrated in FIG. 4, a patterned semiconductor layer 36 such as a poly-crystalline silicon layer is formed on the buffer layer 34. In the present embodiment, the pattered light-absorbing layer 32, the buffer layer 34 and the patterned semiconductor layer 36 are defined by utilizing the same mask through a lithography and etching process but not limited. Moreover, the pattered light-absorbing layer 32 and the pattered semiconductor layer 36 substantially have the same size and corresponding shapes, such that the pattered light-absorbing layer 32 can shield the pattered semiconductor layer 36 to prevent the photo leakage current of the thin film transistor due to backlight illumination without influencing the aperture ratio of the display panel.

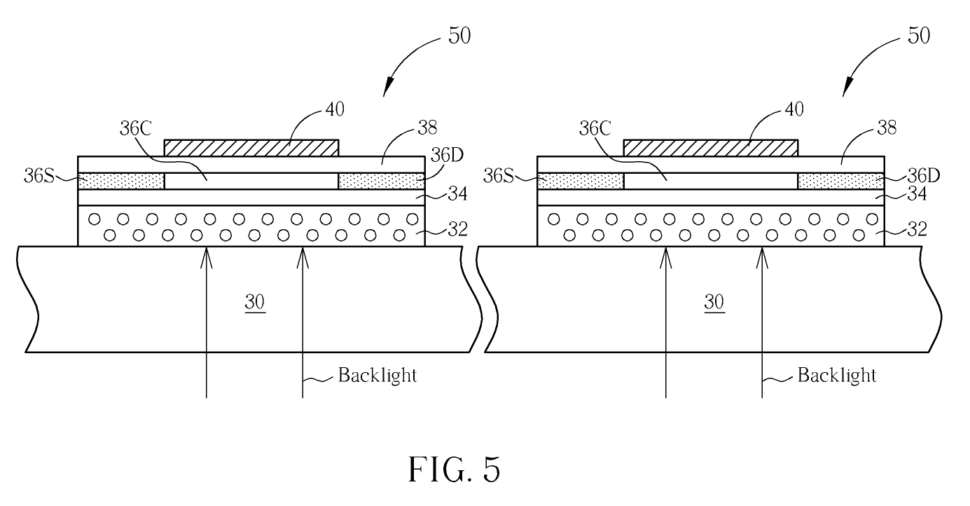

As illustrated in FIG. 5, a gate insulating layer 38 is subsequently formed on the patterned semiconductor layer 36, and a gate electrode 40 is formed on the gate insulating layer 38. Following that, a channel region 36C is formed on the position of the patterned semiconductor layer 36 corresponding to the gate electrode 40 by an ion-implantation process, and a source region 36S and a drain region 36D are formed respectively on two opposite sides of the channel region 36C in the patterned semiconductor layer 36, such that a thin film transistor 50 is fabricated.

From above-mentioned description we know, the light-absorbing layer 32 is disposed on the bottom of the semiconductor layer 36 of the thin film transistor 50 of the present invention, such that the backlight can be absorbed and the photo leakage current of the thin film transistor 50 can be therefore prevented. The light-absorbing layer 32 may preferably be high absorptive materials within the wavelength range of the backlight (the major wavelength range of backlight located on visible wavelength range), such that the backlight can be efficiently shielded. In the aforementioned embodiment, the material of the light-absorbing layer 32 is a silicon-rich dielectric material, which includes nanocrystalline silicon, but is not limited. Other suitable light-absorbing materials can also be employed in the present invention.

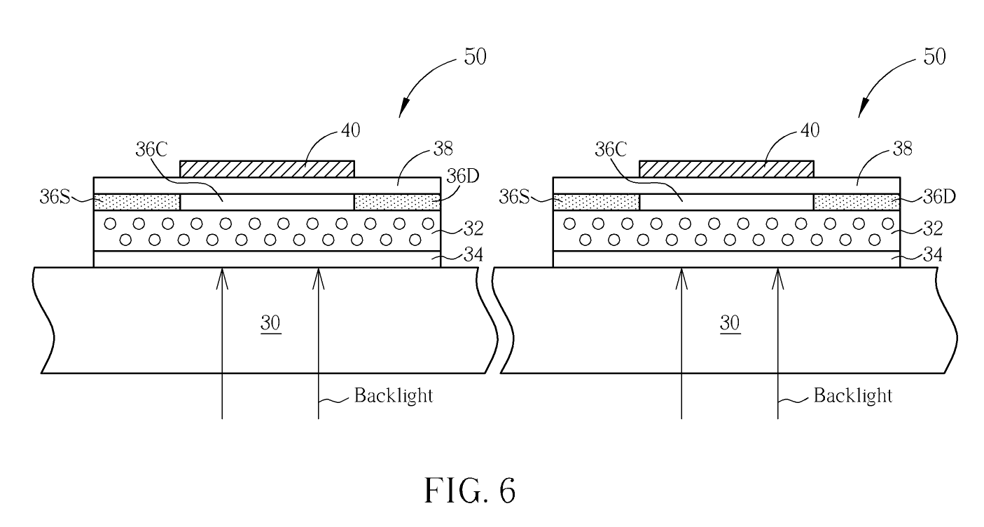

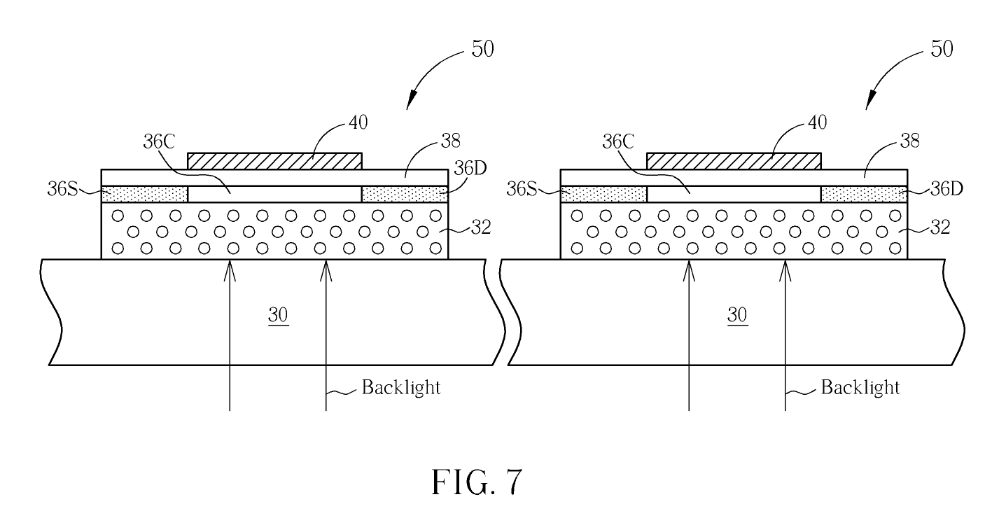

FIG. 6 and FIG. 7 illustrate the schematic diagrams of another two embodiments of the thin film transistor of the present invention, wherein the same devices are denoted by the same numerals in these embodiments for emphasizing the differences between these embodiments. As illustrated in FIG. 6, in the present embodiment, the light-absorbing layer 32 is formed prior to the formation of the buffer layer 34, and consequently the patterned light-absorbing layer 32 is disposed under the bottom of the buffer layer 34. In the present embodiment, the buffer layer 34 can be a single-layered structure such as a buffer oxide layer or a buffer nitride layer, or can be a composite-layered structure such as a composite layer including a buffer oxide layer and a buffer nitride layer. As illustrated in FIG. 7, because the patterned light-absorbing layer 32 is also able to prevent impurities from diffusion, the thin film transistor 50 of the present embodiment consequently has a patterned light-absorbing layer 32 without disposing a buffer layer.

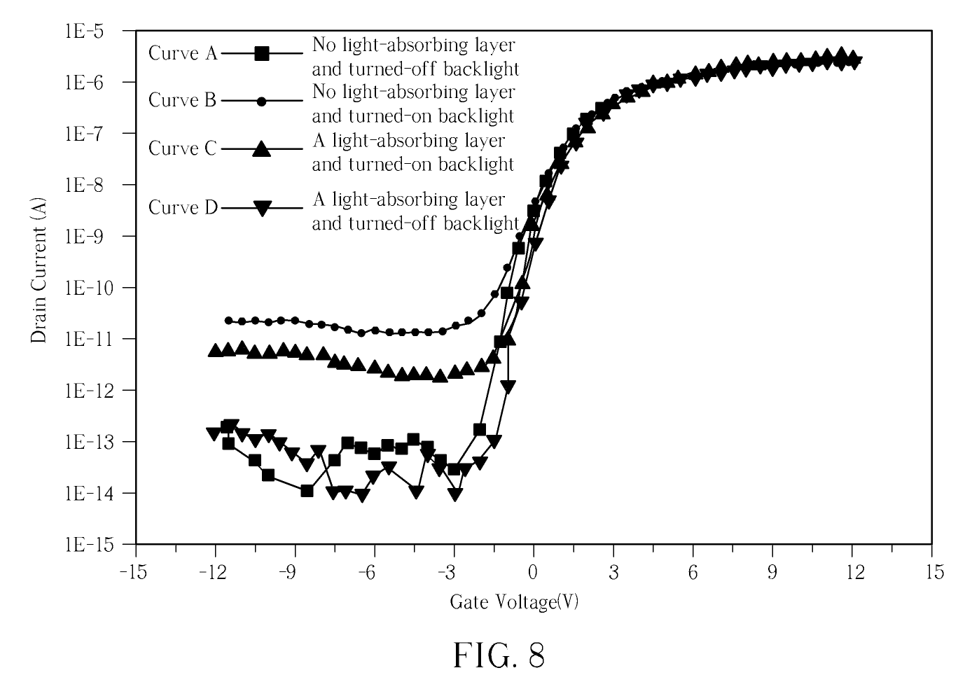

FIG. 8 illustrates the plot of the drain current versus gate-source voltage of the thin film transistor. FIG. 8 includes four curves and the experimental conditions are described as follows:

Curve A: No light-absorbing layer is disposed, and the backlight is turned off;

Curve B: No light-absorbing layer is disposed, and the backlight is turned on (the luminance is 5000 nits);

Curve C: A light-absorbing layer (a silicon-rich dielectric layer having a thickness between 2000 angstrom (Å) and 3000 angstrom (Å)) is disposed, and the backlight is turned on; and

Curve D: A light-absorbing layer is disposed, and the backlight is turned off.

As illustrated in FIG. 8, before the gate voltage rises to the threshold voltage, the drain current of the thin film transistor with a light-absorbing layer (as shown in curve C) is obviously smaller than that without a light-absorbing layer (as shown in curve B) under the condition of a turn-on backlight.

It can be seen that the light-absorbing layer disposed on the thin film transistor of the display panel of the present invention actually eliminates the problem of the leakage current and improves the reliability of the thin film transistor.

Those skilled in the art will readily observe that numerous modifications and alterations of the device and method may be made while retaining the teachings of the invention.

What is claimed is:

1. A thin film transistor (TFT) formed on a transparent substrate, the thin film transistor comprising:
a patterned semiconductor layer disposed on the transparent substrate, the patterned semiconductor layer comprising:
a channel region;
a source region and a drain region disposed on two opposite sides of the channel region in the patterned semiconductor layer;
a gate insulating layer disposed on the patterned semiconductor layer;
a gate electrode disposed on the gate insulating layer; and
a patterned light-absorbing layer disposed between the transparent substrate and the patterned semiconductor layer.

2. The thin film transistor of claim 1, wherein the patterned light-absorbing layer comprises a silicon-rich dielectric layer.

3. The thin film transistor of claim 2, wherein the silicon-rich dielectric layer comprises a silicon-rich silicon oxide layer, a. silicon-rich silicon nitride layer or a silicon-rich silicon oxynitride layer.

4. The thin film transistor of claim 2, wherein an index of refraction of the silicon-rich dielectric layer is between 1.7 and 3.7.

5. The thin film transistor of claim 1, wherein a thickness of the patterned light-absorbing layer is between 100 nm and 300 nm.

6. The thin film transistor of claim 2, wherein the silicon-rich dielectric layer comprises a nanocrystalline silicon dielectric layer.

7. The thin film transistor of claim 6, wherein a diameter of a nanocrystalline silicon in the nanocrystalline silicon dielectric layer is substantially between 5 angstrom (Å) and 500 angstrom (Å).

8. The thin film transistor of claim 1, wherein the patterned light-absorbing layer substantially shields the patterned semiconductor layer.

9. The thin film transistor of claim 1, further comprising a buffer layer disposed between the patterned semiconductor layer and the patterned light-absorbing layer.

10. The thin film transistor of claim 9, wherein the buffer layer comprises a silicon oxide buffer layer or a silicon nitride buffer layer.

11. A thin film transistor substrate applied to a display panel, the thin film transistor substrate comprising:
a transparent substrate; and
a plurality of thin film transistors disposed on the transparent substrate, and each thin film transistor comprising:
a patterned semiconductor layer comprising:
a channel region;
a source region and a drain region disposed on two opposite sides of the channel region in the patterned semiconductor layer;
a gate insulating layer disposed on the patterned semiconductor layer;
a gate electrode disposed on the gate insulating layer; and
a patterned light-absorbing layer disposed between the transparent substrate and the patterned semiconductor layer.

12. The thin film transistor substrate of claim 11, wherein the patterned light-absorbing layer comprises a silicon-rich dielectric layer.

13. The thin film transistor substrate of claim 12, wherein the silicon-rich dielectric layer comprises a silicon-rich silicon oxide layer, a. silicon-rich silicon nitride layer or a silicon-rich silicon oxynitride layer.

14. The thin film transistor substrate of claim 12, wherein an index of refraction of the silicon-rich dielectric layer is between 1.7 and 3.7.

15. The thin film transistor substrate of claim 11, wherein a thickness of the patterned light-absorbing layer is between 100 nm and 300 nm.

16. The thin film transistor substrate of claim 12, wherein the silicon-rich dielectric layer comprises a nanocrystalline silicon dielectric layer.

17. The thin film transistor substrate of claim 16, wherein a diameter of a nanocrystalline silicon in the nanocrystalline silicon dielectric layer is substantially between 5 angstrom (Å) and 500 angstrom (Å).

18. The thin film transistor substrate of claim 11, wherein the patterned light-absorbing layer substantially shields the patterned semiconductor layer.

19. The thin film transistor substrate of claim 11, further comprising a buffer layer disposed between the patterned semiconductor layer and the patterned light-absorbing layer.

20. The thin film transistor substrate of claim 19, wherein the buffer layer comprises a silicon oxide buffer layer or a silicon nitride buffer layer.

21. A method of fabricating a thin film transistor, comprising:
providing a transparent substrate;
subsequently forming a patterned light-absorbing layer and a patterned semiconductor layer on the transparent substrate in sequence, wherein the patterned light-absorbing layer substantially shields the patterned semiconductor layer; and
forming a thin film transistor on the patterned semiconductor layer.

22. The method of claim 21, wherein the steps of forming the thin film transistor on the patterned semiconductor layer comprising:
forming a gate insulating layer on the patterned semiconductor layer, and
forming a gate electrode on the gate insulating layer; and
forming a channel region in the patterned semiconductor layer, and a source region and a drain region on two opposite sides of the channel region in the patterned semiconductor layer.

23. The method of claim 21, further comprising forming a buffer layer on the patterned light-absorbing layer prior to forming the pattern semiconductor layer.

24. The method of claim 23, wherein the buffer layer comprises a silicon oxide buffer layer or a silicon nitride buffer layer.

25. The method of claim 21, wherein the patterned light-absorbing layer comprises a silicon-rich dielectric layer.

26. The method of claim 25, wherein the silicon-rich dielectric layer comprises a nanocrystalline silicon dielectric layer.

27. The method of claim 26, wherein a diameter of a nanocrystalline silicon in the nanocrystalline silicon dielectric layer is substantially between 5 angstrom (Å) and 500 angstrom (Å).
